(19) United States
(12) Patent Application Publication
(10) Pub. No.: US 2017/0033181 A1
(43) Pub. Date: Feb. 2, 2017

(54) METHODS OF FORMING REPLACEMENT FINS COMPRISED OF MULTIPLE LAYERS OF DIFFERENT SEMICONDUCTOR MATERIALS

(71) Applicant: GLOBALFOUNDRIES Inc., Grand Cayman (KY)

(72) Inventors: Timothy J. McArdle, Hopewell Junction, NY (US); Judson R. Holt, Wappingers Falls, NY (US); Bharat V. Krishnan, Mechanicville, NY (US); Jody A. Fronheiser, Delmar, NY (US)

(21) Appl. No.: 14/810,574

(22) Filed: Jul. 28, 2015

(51) Int. Cl. H01L 29/10; H01L 21/306; H01L 29/66; H01L 29/423; H01L 29/165; H01L 21/02; H01L 21/311

(52) U.S. Cl. CPC H01L 29/1054; H01L 21/0243; H01L 21/02107; H01L 21/30604; H01L 21/02532; H01L 21/31116; H01L 29/42356; H01L 29/165; H01L 29/66795; H01L 21/02527; H01L 21/02636

(57) ABSTRACT

One illustrative method disclosed herein includes, among other things, individually forming alternating layers of different semiconductor materials in a substrate fin cavity so as to form a multi-layer fin above a recessed substrate fin, wherein each of the layers of different semiconductor materials is formed to a final thickness that is less than a critical thickness of the layer of different semiconductor material being formed, recessing the layer of insulating material so as to expose at least a portion of the multi-layer fin above a recessed upper surface of the layer of insulating material and forming a gate structure around at least a portion of the of exposed the multi-layer fin.

### BACKGROUND OF THE INVENTION

1. Field of the Invention

Generally, the present disclosure relates to the manufacture of semiconductor devices, and, more specifically, to various methods of forming replacement fins comprised of multiple layers of different semiconductor materials and the resulting FinFET device.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein so-called metal oxide field effect transistors (MOSFETs or FETs) represent one important type of circuit element that substantially determines performance of the integrated circuits. A conventional FET is a planar device that typically includes a source region, a drain region and a channel region that is positioned between the source region and the drain region, and a gate electrode positioned above the channel region. Current flow through the FET is controlled by controlling the voltage applied to the gate electrode. For example, for an NMOS device, if there is no voltage applied to the gate electrode, then there is no current flow through the NMOS device (ignoring undesirable leakage currents, which are relatively small). However, when an appropriate positive voltage is applied to the gate electrode, the channel region of the NMOS device becomes conductive, and electrical current is permitted to flow between the source region and the drain region through the conductive channel region.

To improve the operating speed of FETs, and to increase the density of FETs on an integrated circuit device, device designers have greatly reduced the physical size of FETs over the past decades. More specifically, the channel length of FETs has been significantly decreased, which has resulted in improving the switching speed and in lowering operation currents and voltages of FETs. However, decreasing the channel length of a FET also decreases the distance between the source region and the drain region. In some cases, this decrease in the separation between the source and the drain makes it difficult to efficiently inhibit the electrical potential of the source region and the channel from being adversely affected by the electrical potential of the drain. This is sometimes referred to as a so-called short channel effect, wherein the characteristic of the FET as an active switch is degraded.

In contrast to a planar FET, there are so-called 3D devices, such as an illustrative FinFET device, which is a three-dimensional structure. FIG. 1A is a perspective view of an illustrative prior art FinFET semiconductor device 10 that is formed above a semiconductor substrate 12. The simplistically depicted device 10 includes three illustrative fins 14, an isolation material 15, a gate structure 16, a sidewall spacer 18 and a gate cap layer 20. The gate structure 16 is typically comprised of a layer of insulating material (not separately shown), e.g., a layer of high-k insulating material, and one or more conductive material layers that serve as the gate electrode for the device 10. In this example, the fins 14 are comprised of a substrate fin portion 14A and an alternative fin material portion 14B. The substrate fin portion 14A may be made of silicon, i.e., the same material as the substrate, and the alternative fin material portion 14B may be made of a material other than the substrate material, for example, silicon-germanium. The fins 14 have a three dimensional configuration: a height H, a width W and an axial length L. The axial length L corresponds the direction of current travel in the device 10 when it is operational, i.e., the gate-length direction. The portions of the fins 14 covered by the gate structure 16 are the channel regions of the FinFET device 10. In a conventional process flow, the portions of the fins 14 that are positioned outside of the spacers 18, i.e., in the source/drain regions of the device 10, may be increased in size or even merged together (not shown in FIG. 1A) by performing one or more epitaxial growth processes. The process of adding epi material on the portions of the fins 14 in the source/drain regions of the device 10 is performed to reduce the resistance of source/drain regions and/or make it easier to establish electrical contact to the source/drain regions.

In the FinFET device 10, the gate structure 16 encloses (or is positioned around) both of the side surfaces and the upper surface of all or a portion of the fins 14 to form a tri-gate structure so as to use a channel having a three-dimensional structure instead of a planar structure. In some cases, an insulating cap layer, e.g., silicon nitride, is positioned at the top of the fins 14 and the FinFET device only has a dual-gate structure (sidewalls only). Unlike a planar FET, in a FinFET device, a channel is formed perpendicular to a surface of the semiconducting substrate so as to increase the drive current per footprint of the device. Also, in a FinFET, the improved gate control through multiple gates on a narrow, fully-depleted semiconductor fin significantly reduces the short channel effects. When an appropriate voltage is applied to the gate electrode of a FinFET device, the surfaces (and the inner portion near the surface) of the fins 14, i.e., the vertically oriented sidewalls and the top upper surface of the fin, form a surface inversion layer or a volume inversion layer that contributes to current conduction. In a FinFET device with a single fin, the “channel-width” is estimated to be about two times (2×) the vertical fin-height plus the width of the top surface of the fin, i.e., the fin width. Multiple fins can be formed in the same foot-print as that of a planar transistor device. Accordingly, for a given plot space (or foot-print), FinFETs tend to be able to generate significantly higher drive current than planar transistor devices. Additionally, the leakage current of FinFET devices after the device is turned “OFF” is significantly reduced as compared to the leakage current of planar FETs, due to the superior gate electrostatic control of the “fin” channel on FinFET devices. In short, the 3D structure of a FinFET device is a superior MOSFET structure as compared to that of a planar FET, especially in the 20 nm CMOS technology node and beyond.

Device manufacturers are under constant pressure to produce integrated circuit products with increased performance and lower production costs relative to previous device generations. Thus, device designers spend a great amount of time and effort to maximize device performance while seeking ways to reduce manufacturing costs and improve manufacturing reliability. As it relates to 3D devices, device designers have spent many years and employed a variety of techniques in an effort to improve the performance, capability and reliability of such devices. Device designers are currently investigating using alternative semiconductor materials, such as so-called SiGe, Ge and III-V materials, to manufacture FinFET devices which are intended to enhance the performance capabilities of such devices, e.g., to enable low-voltage operation without degrading their operating speed.

However, the integration of such alternative materials on silicon substrates (the dominant substrates used in the industry) is non-trivial due to, among other issues, the large difference in lattice constants between such alternative materials and silicon. That is, with reference to FIG. 1A, the lattice constant of the alternative fin material portion 14B of the fin 14 may be substantially greater than the lattice constant of the substrate fin portion 14A of the fin 14. As a result of this mismatch in lattice constants, an unacceptable number of defects, such as, stacking faults, misfit dislocations, threading dislocations, etc., may be formed or created in the alternative fin material portion 14B. Such defects are not desirable in that they limit device performance in high performance FinFET devices. FIG. 1B is a TEM photograph of a cross-section of an illustrative fin 14 comprised of a silicon substrate fin 14A and Si_{0.5}Ge_{0.5} alternative fin portion 14B. The cross-section is taken through the width W of the fin 14. The height direction “H” of the fin 14 is also indicated in FIG. 1B.

With respect to forming such lattice-mismatched materials on one another, there is a concept that is generally referred to as the “critical thickness” (“CT”) of a material. The term “critical thickness” generally refers to materials that are in one of three conditions, i.e., so-called “stable,” “metastable” or “relaxed-with-defects” conditions. These three conditions also generally reflect the state of the strain on the material. That is, a stable material is in a fully-strained condition that is 100% strained in at least one crystalline plane of the material. FIG. 1C is a graph taken from an article entitled “Silicon-Germanium Strained Layer Materials in Microelectronics” by Douglas J. Paul that was published in Advanced Materials magazine (11(3), 101-204 (1999)). FIG. 1C graphically depicts these three conditions for blank (unpatterned) silicon-germanium materials (Si₁₋ₓGeₓ; x=0-1) that are formed over a relatively large area. The vertical axis is the critical thickness in nanometers. The horizontal axis is the concentration of germanium in the silicon-germanium material. At the leftmost point on the horizontal axis is pure silicon (Ge concentration equals 0.0). At the rightmost point on the horizontal axis is pure germanium (Ge concentration equals 1.0). The two curves R and S define the stable, metastable and relaxed-with-defects regions for silicon-germanium materials having differing germanium concentration levels. Above and to the right of curve R are materials that are in the relaxed-with-defects condition. Below and to the left of the curve S are materials that are in the stable condition. The region between the two curves R and S defines the region where materials are in the metastable condition.

With reference to FIG. 1C, a layer of pure germanium (Ge concentration equal to 1.0) may be in the stable condition at a thickness up to about 1-2 nm (point CT1) and it may relax beyond about 4 nm (point CT2). Between about 2-4 nm, germanium is in a so-called “metastable condition” meaning it can easily relax if it is subjected to a relatively high temperature anneal. In contrast, a layer of silicon-germanium with a 50% concentration of germanium may be in the stable condition at thicknesses up to about 4 nm (point CT3) and it may be in a metastable condition for thicknesses between about 4-30 nm (point CT4). Above a thickness of about 30 nm, a layer of silicon-germanium with a 50% concentration of germanium will be in the relaxed-with-defects condition. A material that is in the relaxed-with-defects condition is a material that contains visible defects that are indicative that the material has relaxed to the point where defects have been formed in the material. Returning to FIG. 1B, in this example, the thickness or height “H” of the alternative fin material 14B is about 35 nm, a thickness greater than the metastable critical thickness for the blank (unpatterned) growth of this material (which is about 30 nm according to FIG. 1C). Accordingly, the alternative fin material 14B is in the relaxed-with-defects condition and defects are visible throughout the alternative fin material 14B with the exception that there may be fewer or no defects in a small region near the interface between the materials 14A/14B. Of course, the numbers in the Paul reference are a guide as the exact numbers may vary across the published literature and they are highly dependent upon the processing conditions.

The presence of defects in an alternative material fin structure would be detrimental to device operations. One process that has been investigated for use in forming such alternative fin materials is known as aspect-ratio-trapping (ART). In general, the ART process involves forming a masking layer, such as silicon dioxide, above a semiconductor substrate, such as silicon, patterning the masking layer to define a trench that exposes the underlying substrate, and performing an epitaxial growth process to form an alternative fin material, e.g., silicon-germanium, on the exposed substrate, wherein the growth is confined within the trench. That is, the ART process involves epitaxially growing fully relaxed, unstrained material hetero-structures in a high aspect-ratio silicon dioxide trench having an aspect ratio of 5 or greater in an attempt to decrease defects. In some applications, the ART process may involve the formation of trenches that have a very high aspect ratio, e.g., about 25-30. Importantly, in the ART process, the trench is made deep enough such that defects generated in the alternative fin material will be trapped at or near the bottom of the original trench and in the sidewalls of the trench positioned slightly above the interface between the substrate material and the alternative fin material. The amount of defects generated and the propagation of such defects will depend upon the crystal orientation of the substrate. The intent of the ART process is that, while the defect-containing fin material is present at or near the bottom of the trench, the upper-most portions of the epitaxially grown alternative fin material will be substantially defect-free material but, importantly, it is an un-strained material. That is, the alternative fin material is fully relaxed in all crystalline planes, e.g., in the crystalline planes that correspond to the axial length direction, height direction and width direction of the fin. This occurs due to the “trapping” of the defects at or near the bottom of the trench, with the result being the formation of substantially defect-free alternative fin material above the defective-containing portions of the alternative fin material in the lower portion of the trench. In principle, the ART process does not present a limitation with respect to the thickness of the lattice-mismatched layer, which is typically fully relaxed, a few 100 nm thick, and with defects intentionally confined close to the bottom interface. The defects are generated along the (111) crystallographic direction of the alternative fin material and they are captured or stopped by the sidewalls of the trench.

In one particular example, as it relates to the formation of P-type FinFET devices, device designers have investigated the use of pure germanium and silicon-germanium, along with a high uniaxial compressive stress, as the fin material so as to improve charge carrier (i.e., holes) mobility in the devices. To be effective, the germanium or silicon-germanium fin material will ideally be formed in a highly-strained, substantially defect-free condition. Several prior art techniques have been attempted in an effort to form such materials, e.g., blanket growth of a germanium or silicon-germanium material on a stress relaxation buffer layer having an intermediate lattice constant between the fin material and the silicon substrate, cladding processes, cladding plus condensation thermal treatment, replacement fin techniques, etc. Unfortunately, the prior art techniques have yet to be able to form highly-strained, substantially defect-free germanium or silicon-germanium in a sufficient thickness so that it may be used in actual devices. In addition, many of the above-mentioned prior art processing techniques are generally incompatible in terms of the thermal budget required to practice the conventional Si baseline integration flows on bulk substrate materials.

The present disclosure is directed to various methods of forming replacement fins comprised of multiple layers of different semiconductor materials and the resulting FinFET device that may solve or reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming replacement fins comprised of multiple layers of different semiconductor materials and the resulting FinFET device. One illustrative method disclosed herein includes, among other things, forming a substrate fin, forming a layer of insulating material in a plurality of trenches adjacent the substrate fin, and performing a fin recess etching process to remove a portion of the substrate fin and define a recessed substrate fin and a substrate fin cavity in the layer of insulating material above the recessed substrate fin. In this example, the method further includes individually forming alternating layers of different semiconductor materials in the substrate fin cavity so as to form a multi-layer fin above the recessed substrate fin, wherein each of the layers of different semiconductor materials is formed to a final thickness that is less than a critical thickness of a layer of different semiconductor material being formed, recessing the layer of insulating material so as to expose at least a portion of the multi-layer fin above a recessed upper surface of the layer of insulating material and forming a gate structure around at least a portion of the exposed multi-layer fin.

Yet another illustrative method disclosed herein includes, among other things, forming a layer of insulating material in a plurality of trenches adjacent a substrate fin, and performing a fin recess etching process to remove a portion of the substrate fin so as to define a recessed substrate fin and a substrate fin cavity in the layer of insulating material above the recessed substrate fin. In this embodiment, the method also includes individually forming layers of semiconductor materials in the substrate fin cavity so as to form a multi-layer fin above the recessed substrate fin by performing the following actions: individually forming a first layer of silicon-germanium (SiₓGe₁₋ₓ), where x ranges from 0 to 0.95, on and in contact with the recessed substrate fin, wherein the first layer of silicon-germanium is formed to a first final thickness that is less than a critical thickness of the first layer of silicon-germanium; individually forming a first layer of silicon on and in contact with the first layer of silicon-germanium (SiₓGe₁₋ₓ), wherein the first layer of silicon is formed to a second final thickness that is less than a critical thickness of the first layer of silicon; individually forming a second layer of silicon-germanium (SiₓGe₁₋ₓ), where x ranges from 0 to 0.95, on and in contact with first layer of silicon, wherein the second layer of silicon-germanium is formed to a third final thickness that is less than a critical thickness of the second layer of silicon-germanium; and individually forming a second layer of silicon on and in contact with the second layer of silicon-germanium (SiₓGe₁₋ₓ), wherein the second layer of silicon is formed to a fourth final thickness that is less than a critical thickness of the second layer of silicon-germanium. In this example, the method also includes recessing the layer of insulating material so as to expose at least a portion of the multi-layer fin above a recessed upper surface of the layer of insulating material and forming a gate structure around at least a portion of the multi-layer fin.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1C depict examples of prior art FinFET devices wherein the fins for the device are comprised of an alternative fin material formed above a substrate fin; and

FIGS. 2A-2J depict various illustrative novel methods disclosed herein for forming replacement fins comprised of multiple layers of different semiconductor materials and the resulting FinFET device.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various methods of forming replacement fins comprised of multiple layers of different semiconductor materials and the resulting FinFET device. The methods disclosed herein may be employed in manufacturing either an N-type device or a P-type device, and the gate structure of such devices may be formed using either so-called “gate-first” or “replacement gate” (“gate-last” or “gate-metal-last”) techniques. As will be readily apparent to those skilled in the art upon a complete reading of the present application, the present method is applicable to a variety of devices, including, but not limited to, logic devices, memory devices, etc., and the methods disclosed herein may be employed to form N-type or P-type semiconductor devices. With reference to the attached figures, various illustrative embodiments of the methods and devices disclosed herein will now be described in more detail.

In the attached drawings, the device 100 is depicted as being formed above a semiconductor substrate 102 comprised of a semiconductor material, such as, for example, a bulk silicon substrate. Thus, the terms “substrate,” “semiconductor substrate” or “semiconducting substrate” should be understood to cover all semiconductor materials. An isolation material (not shown) may be formed in the substrate 102 to define illustrative spaced-apart active regions in the substrate 102. The isolation regions may be formed using traditional techniques, e.g., traditional shallow trench isolation regions may be formed in the substrate 102. In the case of the illustrative FinFET devices disclosed herein, the isolation regions may be formed before or after the formation of the fin structures that will be formed as described more fully below.

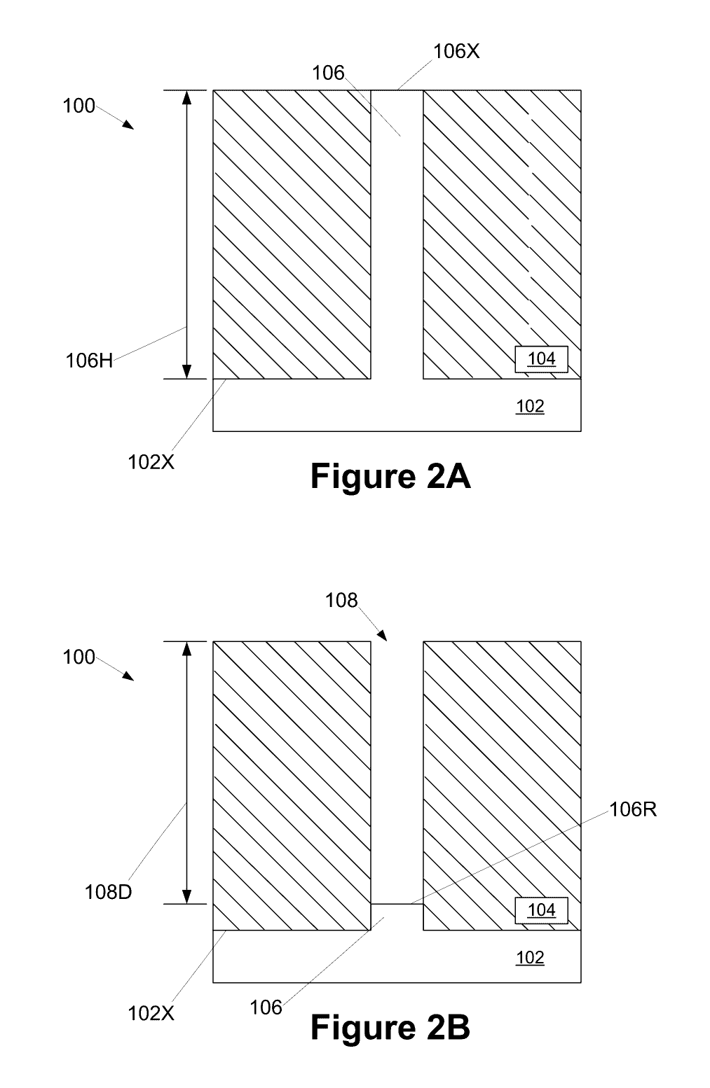

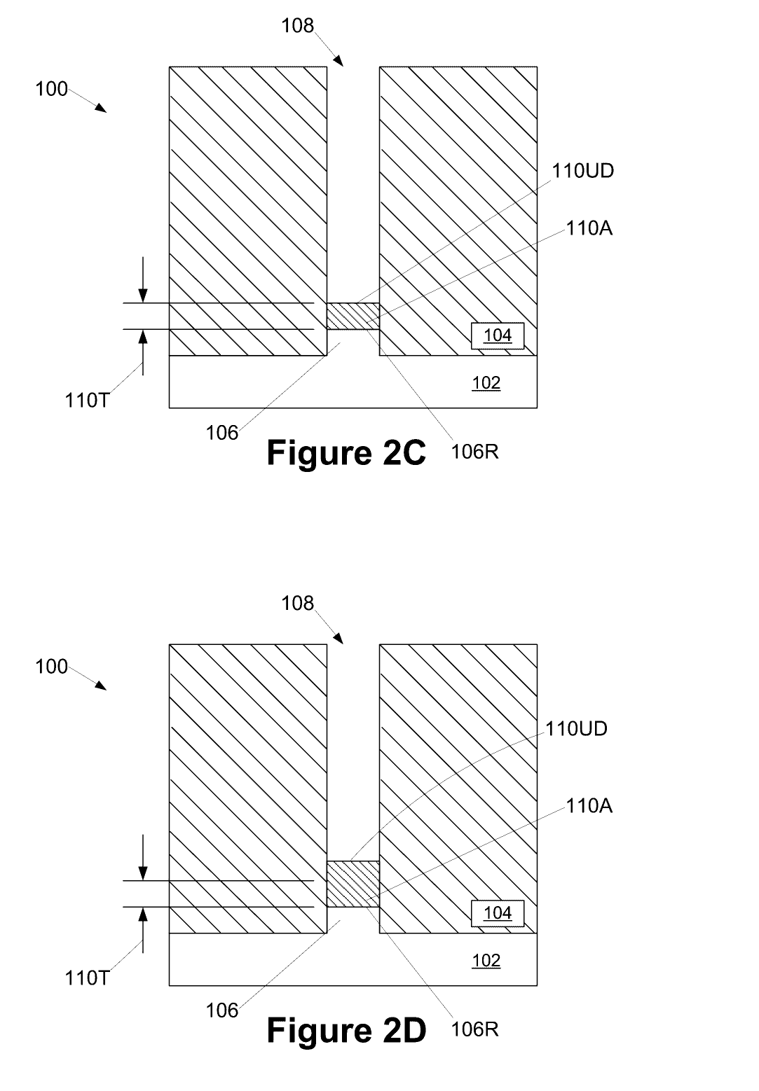

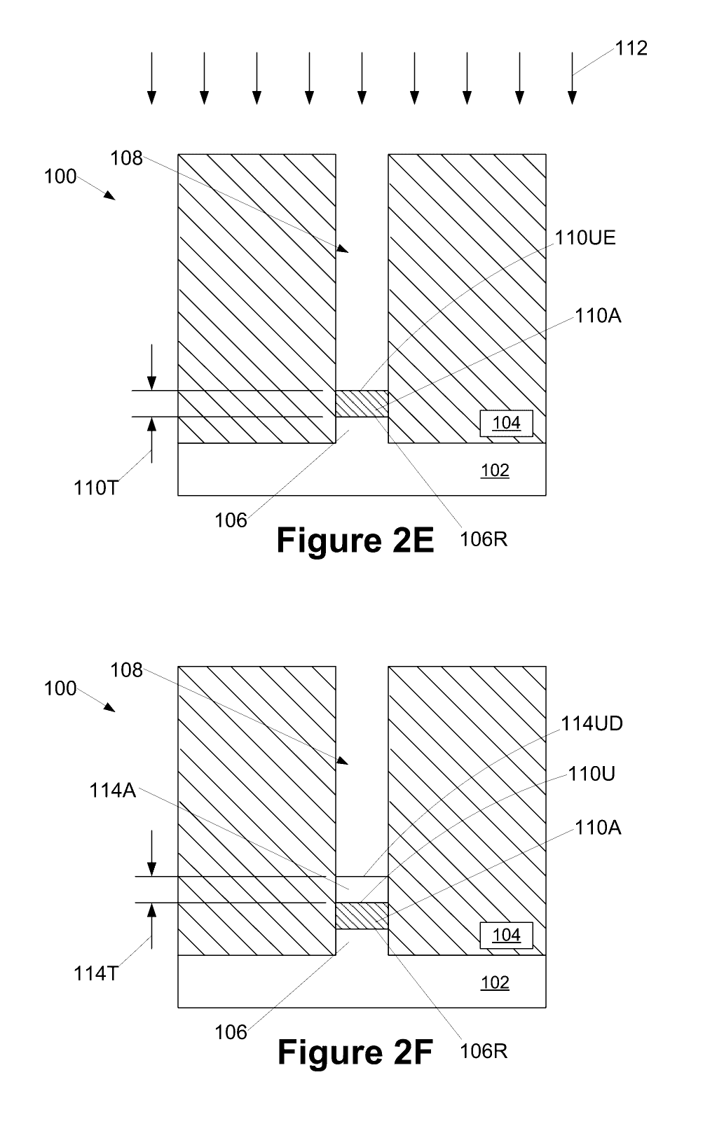

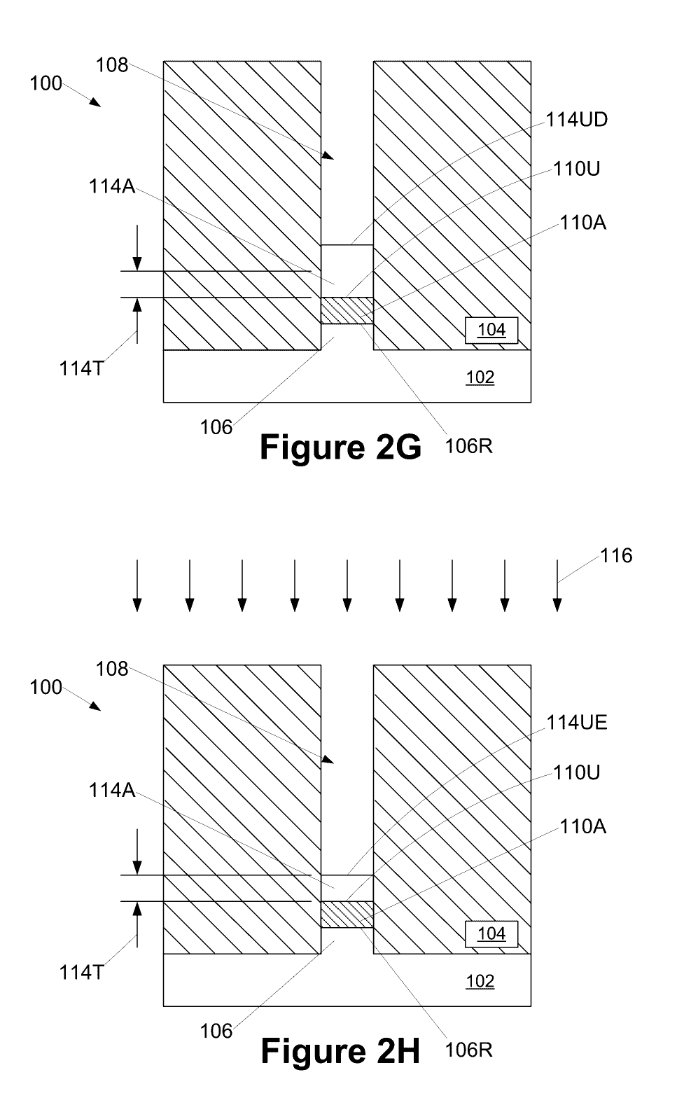

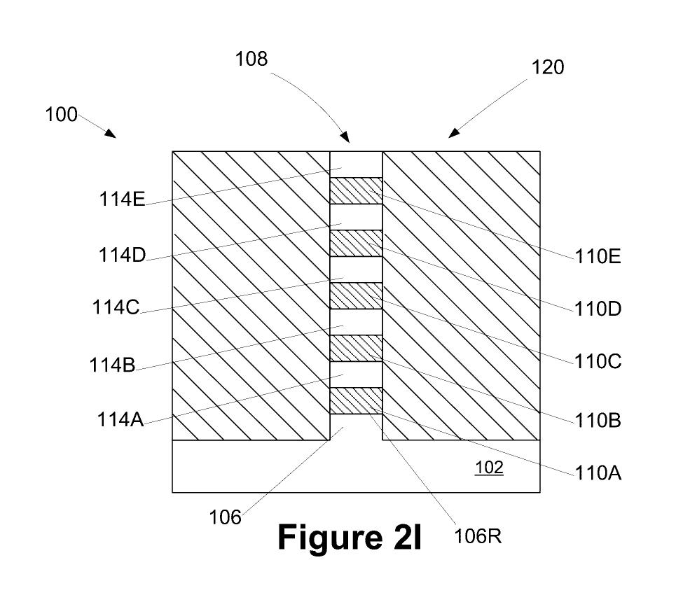

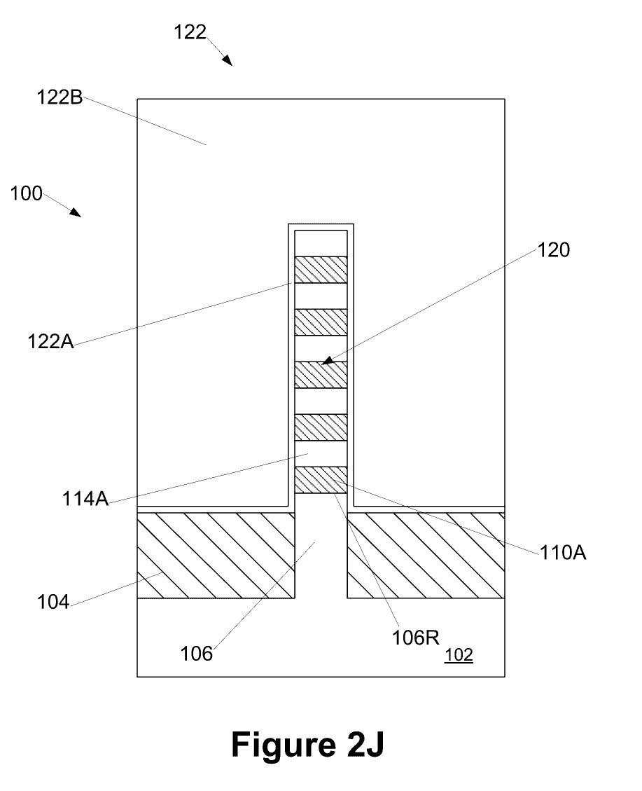

FIGS. 2A-2J depict various illustrative novel methods of forming replacement fins comprised of multiple layers of different semiconductor materials and the resulting FinFET device. FIG. 2A depicts the device 100 after several process operations were performed. First, one or more etching processes, e.g., anisotropic etching processes, were performed through a patterned etch mask (not shown) to define a plurality of fin-formation trenches 102X in the substrate 102. The formation of the trenches 102X results in the formation of an initial substrate fin structure 106. Thereafter, a layer of insulating material 104, such as a layer of silicon dioxide, was formed in the trenches 102X adjacent the substrate fin 106. In one illustrative embodiment, the layer of insulating material 104 may be formed by blanket depositing the initial layer of insulating material across the device so as to over-fill the trenches 102X. Thereafter, an optional chemical mechanical polishing (CMP) process may be performed to planarize the upper surface of the layer of material 104 thereby exposing the upper surface 106X of the substrate fin 106. The layer of material 104 may be comprised of a variety of different materials, such as silicon dioxide, etc., and it may be formed by performing a variety of techniques, e.g., chemical vapor deposition (CVD), etc.

The width and height of the substrate fin structure 106, as well as the overall size, shape and configuration of the fin-formation trenches 102X may vary depending on the particular application. In one illustrative embodiment, based on current day technology, the height 106H of the substrate fin 106 (i.e., the depth the trenches 102X) may range from approximately 5-200 nm and the lateral width of the substrate fin 106 may be about 20-30 nm or less.

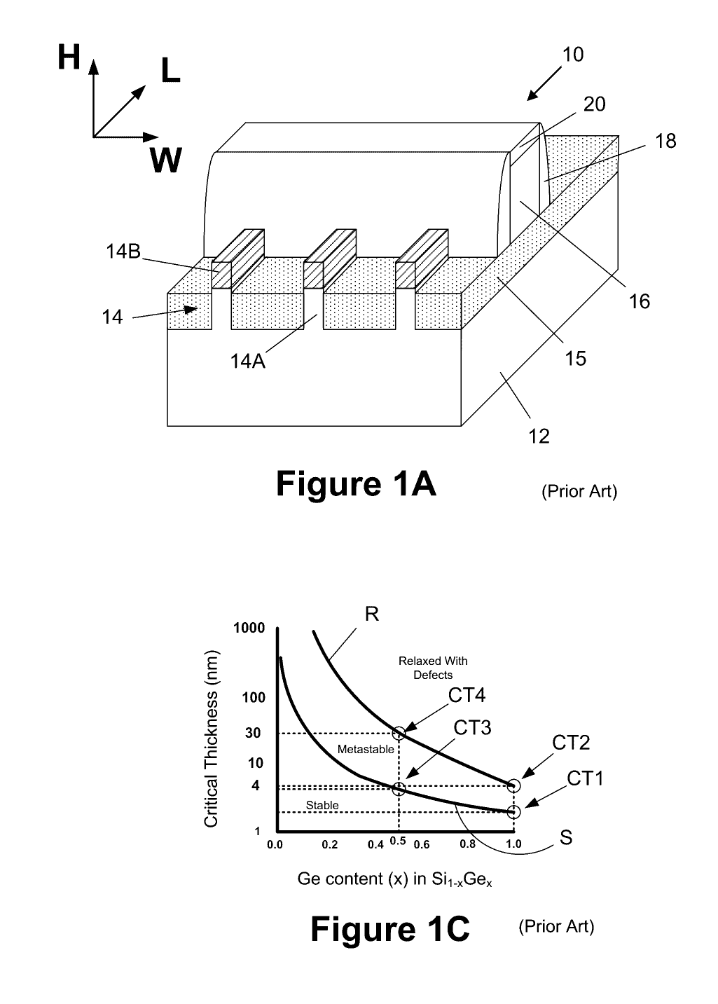

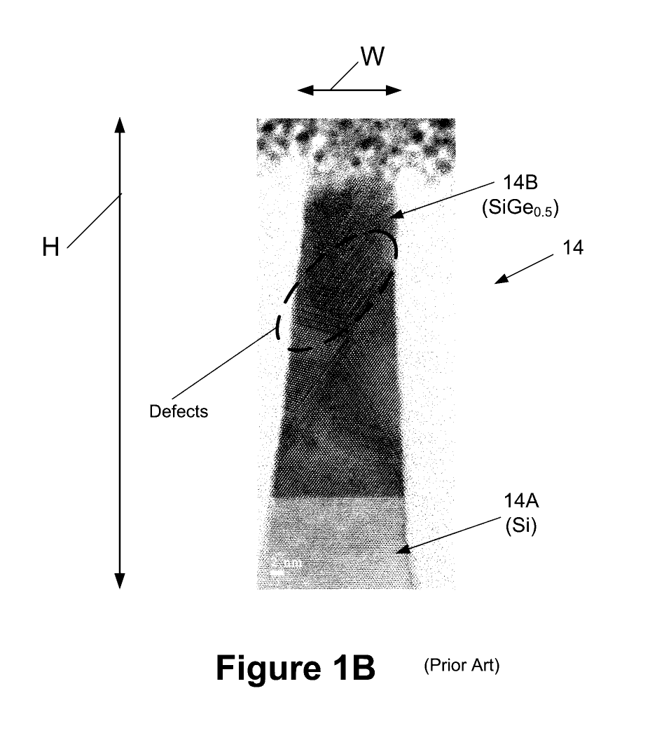

In the illustrative examples depicted in the attached drawings, the substrate fin 106 and the fin-formation trenches 102X are depicted as having a uniform and generally rectangular configuration. In the attached figures, the fin-formation trenches 102X are depicted as having been formed by performing an anisotropic etching process that results in the fin-formation trenches 102X having a schematically depicted, generally rectangular configuration. In an actual real-world device, the sidewalls of the fin-formation trenches 102X may be somewhat inwardly tapered, although that configuration is not depicted in the attached drawings. As a result, the sidewalls of the substrate fin 106 may also be tapered, much like the sidewall of the fin shown in FIG. 1B. Thus, the size and configuration of the fin-formation trenches 102X, and the manner in which they are made, as well as the general configuration of the substrate fin 106, should not be considered a limitation of the present invention. For ease of disclosure, only the substantially rectangular fin-formation trenches 102X and substrate fin 106 will be depicted in the subsequent drawings. Moreover, the device 100 may be formed with any desired number of fins 106.

FIG. 2B depicts the device 100 after a fin recess etching process was performed to remove a portion of the substrate fin 106 and thereby define a substrate fin cavity 108 above a recessed upper surface 106R of the substrate fin 106 and between the insulating material 104. The depth 108D of the substrate fin cavity 108 may vary depending on the particular application. In one illustrative embodiment, based on current day technology, the depth 108D may range from approximately 5-20 nm. The fin recess etching process may be a timed, wet or dry etching process.

FIG. 2C depicts the device 100 after a first layer of semiconductor material 110A was formed in the substrate fin cavity 108 on the recessed upper surface 106R of the substrate fin 106. Importantly, the first layer of semiconductor material 110A has a final thickness 110T that is less than the critical thickness (un-patterned) for the semiconductor material 110A or it may simply be formed to a thickness 110T that is less than about 5 nm. The first layer of semiconductor material 110A is made of a material that is different from that of the substrate fin 106. For example, in one illustrative embodiment, the first layer of semiconductor material 110A may be a layer of silicon-germanium (SiₓGe₁₋ₓ), where x ranges from 0 to 0.95.

The first layer of semiconductor material 110A may be formed using two different techniques such that it has the desired final thickness 110T. In one embodiment, as shown in FIG. 2C, the first layer of semiconductor material 110A may be formed to its desired final thickness 110T by directly depositing the first layer of semiconductor material 110A to the desired thickness. More specifically, in the embodiment shown in FIG. 2C, an epitaxial deposition process was performed to form the first layer of semiconductor material 110A such that the as-deposited thickness of the as-deposited first layer of semiconductor material 110A (having an as-deposited upper surface 110UD) is equal to the final thickness 110T.

In another embodiment, as shown in FIGS. 2D-2E, the first layer of semiconductor material 110A (having an as-deposited upper surface 110UD) may be initially deposited to a thickness that is greater than the final target thickness 110T, as shown in FIG. 2D. For example, the overly thick first layer of semiconductor material 110A may be initially formed to a thickness of about 5-15 nm. Thereafter, as shown in FIG. 2E, a recess etching process 112 may be performed to reduce the thickness of the overly thick as-deposited first layer of semiconductor material 110A (having an as-etched upper surface 110UE) such that it now has a thickness that is equal to the final target thickness 110T. The recess etching process 112 may be a timed, wet or dry etching process. The recess etching process 112 is performed to remove portions of the overly thick first layer of semiconductor material 110A that contains an unacceptable number of defects, i.e., an unacceptable defect density level. In general, the portions of the overly thick first layer of semiconductor material 110A near the interface with the substrate fin 106 should have a lower defect density level than portions more remote from the interface. Using either technique, if desired, a small amount of carbon, e.g., less than about 1%, may be optionally added to the first layer of semiconductor material 110A when it is initially formed, i.e., the carbon may be added during the epitaxial deposition process. The addition of carbon may tend to reduce the strain by compensation for the lattice parameter.

FIG. 2F depicts the device 100 after a second layer of semiconductor material 114A was formed in the substrate fin cavity 108 on the upper surface 110U (as-deposited or etched) of the first layer of semiconductor material 110A. Importantly, the second layer of semiconductor material 114A has a final thickness 114T that is less than the critical thickness (un-patterned) for the semiconductor material 114A or it may simply be formed to a thickness 110T that is less than about 5 nm. The second layer of semiconductor material 114A is made of a material that is different than the material of the first layer of semiconductor material 110A. For example, in one illustrative embodiment, the second layer of semiconductor material 114A may be a layer of silicon. In the depicted example, the second layer of semiconductor material 114A may be made of the same material as that of the substrate fin 106, e.g., silicon, although such a material configuration is not required in all applications.

As with the first layer of semiconductor material 110A, the second layer of semiconductor material 114A may be formed using two different techniques such that it has the desired final thickness 114T. In one embodiment, as shown in FIG. 2F, the second layer of semiconductor material 114A may be formed to its desired final thickness 114T by directly depositing the second layer of semiconductor material 114A to the desired thickness. More specifically, in the embodiment shown in FIG. 2F, an epitaxial deposition process was performed to form the second layer of semiconductor material 114A such that the as-deposited thickness of the as-deposited second layer of semiconductor material 114A (having an as-deposited upper surface 114UD) is equal to the final thickness 114T.

In another embodiment, as shown in FIGS. 2G-2H, the second layer of semiconductor material 114A (having an as-deposited upper surface 114UD) may be initially deposited to a thickness that is greater than the final target thickness 114T, as shown in FIG. 2G. For example, the overly thick second layer of semiconductor material 114A may be initially formed to a thickness of about 5-15 nm. Thereafter, as shown in FIG. 2H, a recess etching process 116 may be performed to reduce the thickness of the overly thick as-deposited second layer of semiconductor material 114A (having an as-etched upper surface 114UE) such that it now has a thickness that is equal to the final target thickness 114T. As before, the recess etching process 116 may be a timed, wet or dry etching process, and it is performed to remove portions of the overly thick second layer of semiconductor material 114A that contain an unacceptable number of defects, i.e., an unacceptable defect density level. In general, the portions of the overly thick second layer of semiconductor material 114A near the interface with the first layer of semiconductor material 110A should have a lower defect density level than portions more remote from the interface. Using either technique, if desired, a small amount of carbon, e.g., less than about 1%, may be optionally added to the second layer of semiconductor material 114A when it is initially formed, i.e., the carbon may be added during the epitaxial deposition process. The addition of carbon may tend to relax strain in the deposited material and/or inhibit defect propagation.

FIG. 2I depicts the device after the above described process operations were repeated so as to substantially fill the substrate fin cavity 108. In the depicted example, five layers (110A-E) of the first layer of semiconductor material 110 and five layers (114A-E) of the second layer of semiconductor material 114 were formed so as to substantially fill the cavity 108. Collectively, the multiple layers of material 110, 114 define a multi-layer fin 120. Of course, the substrate fin cavity 108 need not be completely filled using the processes disclosed herein. Additionally, the number of layers of material 110, 114 need not be the same in all applications, and the uppermost layer of the multi-layer fin 120 may be a layer of either the first layer of semiconductor material 110 or the second layer of semiconductor material 114. The multiple layers of material 110 need not each be formed to the same final thickness 110T, although that may the case in some applications. For example, the layers 110A-B may each be formed to a thickness 110T of about 5 nm, while the layer 110C may be formed to a thickness 110T of about 4 nm and the layers 110D-E may be formed to a thickness of about 3 nm each. Similarly, the multiple layers of material 110 need not each be formed so as to have the same germanium concentration, although that may the case in some applications. For example, the layers 110A-B may each be formed of SiGe_{0.5}, while the layer 110C may be formed of SiGe_{0.75} and the layers 110D-E may be formed of substantially pure germanium. Similarly, the multiple layers of material 114 need not each be formed to the same final thickness 114T or the have the same material composition, although that may the case in some applications.

At the point of processing depicted in FIG. 2I, the illustrative FinFET device 100 may be completed using traditional fabrication techniques. For example, FIG. 2J depicts the device 100 after the layer of insulating material 104 was recessed to expose or “reveal” a desired amount of the multi-layer fin 120 and after an illustrative gate structure 122 was formed for the device 100 around the multi-layer fin 120. In one illustrative embodiment, the schematically depicted gate structure 122 includes an illustrative gate insulation layer 122A and an illustrative gate electrode 122B. The gate insulation layer 122A may be comprised of a variety of different materials, such as, for example, silicon dioxide, a so-called high-k (k greater than 10) insulation material (where k is the relative dielectric constant), etc. Similarly, the gate electrode 122B may also be comprised of a material such as polysilicon or amorphous silicon, or it may be comprised of one or more metal layers that act as the gate electrode 122B. As will be recognized by those skilled in the art after a complete reading of the present application, the gate structure 122 of the device 100 depicted in the drawings, i.e., the gate insulation layer 122A and the gate electrode 122B, is intended to be representative in nature. That is, the gate structure 122 may be comprised of a variety of different materials and it may have a variety of configurations, and the gate structure 122 may be made using either the so-called “gate-first” or “replacement gate” techniques.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

1. A method, comprising:
forming a plurality of trenches in a substrate to thereby define a substrate fin;
forming a layer of insulating material in said plurality of trenches adjacent said substrate fin;
performing a fin recess etching process to remove a portion of said substrate fin and define a recessed substrate fin and a substrate fin cavity in said layer of insulating material above said recessed substrate fin;
individually forming a plurality of alternating layers of different semiconductor materials in said substrate fin cavity so as to form a multi-layer fin above said recessed substrate fin, wherein each of said alternating layers of different semiconductor materials is formed to a final thickness that is less than a critical thickness of the layer of different semiconductor being formed and wherein individually forming each of said plurality of alternating layers comprises:
epitaxially depositing an initial layer of material for each of said plurality of alternating layers having an initial thickness; and
performing a recess etching process on said initial layer of material to reduce its initial thickness to said final thickness;
recessing said layer of insulating material so as to expose at least a portion of said multi-layer fin above a recessed upper surface of said layer of insulating material; and
forming a gate structure around at least a portion of said exposed portion of said multi-layer fin after forming said multi-layer fin.

2.-5. (canceled)

6. The method of claim 1, wherein each of said individually formed alternating layers of different semiconductor materials have the same final thickness.

7. The method of claim 1, wherein each of said individually formed alternating layers of different semiconductor materials has a final thickness that is equal to 5 nm or less.

8. The method of claim 1, wherein at least two of said individually formed alternating layers of different semiconductor materials have different final thicknesses.

9. The method of claim 1, wherein said substrate is comprised of silicon and wherein individually forming said alternating layers of different semiconductor materials comprises:
individually forming a first layer of silicon-germanium (SiₓGe₁₋ₓ), where x ranges from 0 to 0.95, on and in contact with said recessed substrate fin;
individually forming a first layer of silicon on and in contact with said first layer of silicon-germanium (SiₓGe₁₋ₓ);
individually forming a second layer of silicon-germanium (SiₓGe₁₋ₓ), where x ranges from 0 to 0.95, on and in contact with said first layer of silicon; and
individually forming a second layer of silicon on and in contact with said second layer of silicon-germanium (SiₓGe₁₋ₓ).

10. The method of claim 9, wherein said first and second layers of silicon-germanium (SiₓGe₁₋ₓ) have the same germanium concentration.

11. The method of claim 1, wherein individually forming said alternating layers of different semiconductor materials comprises individually forming at least one of said alternating layers of different semiconductor materials by performing an epitaxial deposition process and introducing carbon into said at least one of said alternating layers of different semiconductor materials during said epitaxial deposition process.

12. The method of claim 11, wherein said carbon concentration is less than 1 percent.

13. The method of claim 1, wherein individually forming said alternating layers of different semiconductor materials comprises individually forming alternating layers of two different semiconductor materials.

14. The method of claim 1, wherein individually forming said alternating layers of different semiconductor materials substantially fills said substrate fin cavity.

15. A method, comprising:
forming a plurality of trenches in a substrate to thereby define a substrate fin;
forming a layer of insulating material in said plurality of trenches adjacent said substrate fin;
performing a fin recess etching process to remove a portion of said substrate fin and define a recessed substrate fin and a substrate fin cavity in said layer of insulating material above said recessed substrate fin;
individually forming layers of semiconductor materials in said substrate fin cavity so as to form a multi-layer fin above said recessed substrate fin by:
individually forming a first layer of silicon-germanium (SiₓGe₁₋ₓ), where x ranges from 0 to 0.95, on and in contact with said recessed substrate fin, wherein said first layer of silicon-germanium is formed to a first final thickness that is less than a critical thickness of said first layer of silicon-germanium;
individually forming a first layer of silicon on and in contact with said first layer of silicon-germanium (SiₓGe₁₋ₓ), wherein said first layer of silicon is formed to a second final thickness that is less than a critical thickness of said first layer of silicon;
individually forming a second layer of silicon-germanium (SiₓGe₁₋ₓ), where x ranges from 0 to 0.95, on and in contact with said first layer of silicon, wherein said second layer of silicon-germanium is formed to a third final thickness that is less than a critical thickness of said second layer of silicon-germanium;
individually forming a second layer of silicon on and in contact with said second layer of silicon-germanium (SiₓGe₁₋ₓ), wherein said second layer of silicon is formed to a fourth final thickness that is less than a critical thickness of said second layer of silicon, and wherein individually forming each of said first layer of silicon-germanium, said first layer of silicon, said second layer of silicon-germanium and said second layer of silicon comprises:
epitaxially depositing an initial layer of material for each of said first layer of silicon-germanium, said first layer of silicon, said second layer of silicon-germanium and said second layer of silicon such that an as-deposited thickness of each of said initial layers of material is greater than the corresponding first, second, third and fourth final thicknesses, respectively; and
performing a recess etching process on each of said initial layers of material to reduce their initial thickness to the corresponding first, second, third and fourth final thicknesses, respectively;
recessing said layer of insulating material so as to expose at least a portion of said multi-layer fin above a recessed upper surface of said layer of insulating material; and
forming a gate structure around at least a portion of said exposed portion of said multi-layer fin after forming said multi-layer fin.

16. The method of claim 15, wherein at least one of said first, second, third and fourth final thicknesses are as-deposited final thicknesses of said first layer of silicon-germanium, said first layer of silicon, said second layer of silicon-germanium and said second layer of silicon, respectively.

17.-19. (canceled)

20. The method of claim 15, wherein each of said first, second, third and fourth final thicknesses are the same thickness.

21. The method of claim 15, wherein each of said first, second, third and fourth final thicknesses are equal to 5 nm or less.

22. The method of claim 21, wherein at least two of said first, second, third and fourth final thicknesses are different thicknesses.

23. The method of claim 15, wherein said first and second layers of silicon-germanium have the same germanium concentration.

24. The method of claim 15, wherein individually forming said first layer of silicon-germanium, said first layer of silicon, said second layer of silicon-germanium and said second layer of silicon, respectively, comprises performing first, second, third and fourth epitaxial deposition processes, respectively, while introducing carbon during each of said first, second, third and fourth epitaxial deposition processes.

25. The method of claim 24, wherein said carbon concentration is less than 1 percent.
